(19) United States
(12) Patent Application Publication
(10) Pub. No.: US 2025/0250148 A1
(43) Pub. Date: Aug. 7, 2025

(54) AUTOMATED PROCESS FOR ESTABLISHING AN INVENTORY OF WORK CARRIED OUT BY LIFTING EQUIPMENT

(71) Applicant: MANITOWOC CRANE GROUP FRANCE, DARDILLY (FR)

(72) Inventors: Simon BUCAS, LYON (FR); Nicolas LARMINIER, LYON (FR); Thomas JUSSEY, OULLINS (FR)

(21) Appl. No.: 18/778,920

(22) Filed: Jul. 20, 2024

(30) Foreign Application Priority Data
Jul. 20, 2023 (FR) 2307776

(51) Int. Cl. B66C 13/46; G06Q 10/0631; G06Q 50/08; G07C 5/00

(52) U.S. Cl. CPC B66C 13/46; G06Q 10/063114; G06Q 50/08; G07C 5/008

(57) ABSTRACT

An automated method for establishing an inventory of categories of carried out work during different periods of time by a lifting machine includes a step of collecting for at least one period of time, by a collection unit, information coming from a control-command unit of the lifting machine. The method also includes a step of processing the information collected to determine carried out work by the lifting machine during the at least one period of time, the carried out work falling within at least one category of work, and to determine at least one parameter associated with the at least one carried out work and/or with the at least one category of carried out work.

### FIELD

The present disclosure concerns the field of construction and civil engineering work, and in particular the monitoring of the technical progress of construction sites in which lifting machine, and more particularly cranes, are present.

### BACKGROUND

It may happen that the progress of certain construction sites diverges significantly from initial forecasts. In this case, it happens that manual chrono-analyses are carried out in order to try to reorganize the remaining work to catch up. These chrono-analyses require at least one person to travel to the site over a period of one to several days. Furthermore, it is impossible to carry out these manual chrono-analyses systematically on all construction sites. As a result, an automated tool for monitoring the progress of carried out work presents a clear advantage for construction sites.

### SUMMARY

The present disclosure therefore aims to propose a solution to all or part of these problems.

To this end, the present disclosure concerns an automated method for establishing an inventory of the categories of work carried out during different periods of time by a lifting machine, the method comprising the following steps:
a step of collecting, for at least one period of time, by a collection unit, information coming from a control-command unit of the lifting machine;
a step of processing, by a local processing unit and/or a remote processing unit, the information collected by the collection unit, to determine work carried out by the lifting machine during the at least one period of time, the carried out work falling within at least one category of carried out work, and to determine at least one parameter associated with the at least one carried out work and/or with the at least one category of carried out work, the processing step comprising an implementation by the local processing unit and/or the remote processing unit of an artificial intelligence algorithm trained during a learning phase to carry out during a predictive phase of the processing step, the artificial intelligence algorithm using at least one contextual information to determine the carried out work and/or the category of carried out work, the contextual information being one of at least one lifting time, one maximum load, a maximum speed, a position of a load pick-up point and a position of a load drop-off point, a location of a delivery point, a location of a storage area.

Thus, the present disclosure proposes to exploit a lifting machine, present on a construction site, to recover data and in particular information coming from the control-command unit of the lifting machine, for example in a continuous manner, which will be used in order to establish one or more usable parameters to establish the actual activity of the lifting machine and thus the progress of the site; the lifting machine generally being a major element of the site, at the heart of most operations/works, such as, but not limited to, concrete casting work, carrying structural elements (beams, double walls, etc.), etc. The advantage of the present disclosure thus lies in this exploitation of the data coming from the control-command unit of the lifting machine, that is to say data coming from a unit present natively on the lifting machine, for monitoring the progress of the work actually carried out, before a possible comparison with the planned work, so as to be able to reliably assess a delay. Thus, the present disclosure does not require the presence and/or integration of additional sensors on the lifting machine. In addition, the present disclosure does not require the use of data external to the concerned site. UItimately, the present disclosure, by taking advantage of the existing material on the lifting machine to extract the necessary information, is simple and inexpensive to implement, and does not require the addition of additional material (additional sensors or other) on the lifting machine.

According to one implementation mode, the present disclosure comprises one or more of the following characteristics, alone or in technically acceptable combination.

According to one implementation mode, the collected information comprises at least one of a load signal, representative of a mass of a load lifted by the lifting machine, a position signal in the space of a hook of the lifting machine, a speed signal representative of a variation of the frequency variators and a signal representative of an electrical state of the lifting machine such as an on or activated state in which the lifting machine is turned on, a deactivated or off state in which the lifting machine is turned off, a standby state in which the lifting gear is in standby mode, a state indicating startup in progress or a state indicating an extinction in progress.

According to one possibility, the electrical state of the lifting machine is provided by the control-command unit of the lifting machine.

According to one possibility, a profile of a load signal coming from the collection step is compared to at least one profile of a model load signal, or typical profile, obtained during the learning phase of the artificial intelligence algorithm, said model load signal profile being representative of a category of carried out work.

According to this possibility, the comparison of the profile of the load signal from the collection step to at least one model load signal profile makes it possible to identify a carried out work or a category of a carried out work by the lifting machine.

According to an implementation mode, a load signal coming from the collection step is compared to a set of model signals determined by a learning phase of the artificial intelligence algorithm.

According to one possibility, the creation of these model signals and their implementation are based on a distance between the signals obtained by a dynamic temporal deformation making it possible to create the model signals and subsequently the category of carried out work by the lifting machine.

According to one possibility, the load signal obtained in the collection step is previously divided into a certain number of lifting cycles limited in time, that is to say represented by a start of lifting and a lifting end.

According to one possibility, the division of the load signal, which makes it possible to extract the different lifting cycles, is carried out by means of a deterministic algorithm, for example

The dynamic time deformation used in the learning step therefore makes it possible to carry out the comparison step, the learning step making it possible to define the different categories of carried out work according to the profile of the load signal while at the comparison step, the identified lifting cycle, that is to say bounded by a start and a lifting end, and normalized is compared via dynamic time deformation to the centroid (representing an averaged cycle for the considered category) of each work category.

According to one implementation mode, the at least one category of carried out work during the at least one period of time comprises at least one of a concrete casting, a transfer of a type of load, a positioning of a load type, a no-load movement, an unloading of a truck of materials.

According to one implementation mode, the at least one category of carried out work during the at least one period of time will be an indefinite category, or a period of inactivity.

According to one implementation mode, the type of load comprises at least one of a concrete bucket, a rubble bucket, one or more construction materials, one or more formwork elements, one or more concrete reinforcement elements, a prefabricated element.

According to one implementation mode, the construction material comprises at least one among a group of props, wall formwork, i.e. a formwork, floor formwork elements.

According to one implementation mode, the prefabricated element comprises at least one of a staircase, a balcony, a double wall.

According to one implementation mode, the at least one parameter associated with the at least one category of carried out work comprises at least one among a duration of work carried out falling within said at least one category of work, a mass of a load lifted during carried out work falling within at least one category of work, a movement of a load lifted during carried out work falling within at least one category of work, an average duration of carried out work, during different periods of time, falling within said category of work, a maximum duration of carried out work, during different periods of time, falling within said category of work, a minimum duration of carried out work, during different periods of time, falling within said category of work, a minimum mass lifted during the carried out work, during different periods of time, falling within said category of work, a maximum mass lifted during the carried out work, during different periods of time, falling within said category of work.

According to one implementation mode, the artificial intelligence algorithm is further trained to classify the at least one carried out work determined during the processing step according to at least one category of work.

According to one implementation mode, the at least one parameter associated with the carried out work is used during the processing step to determine at least one other parameter associated with the at least one category of work.

According to one implementation mode, the contextual information is at least one of a location of a concrete delivery point by a mixer truck, a location of a delivery point of materials or a raw material by a delivery truck, a location of a storage point for materials or a raw material delivered by a delivery truck.

According to one implementation mode, the contextual information is associated with the at least one parameter determined during the processing step.

According to one implementation mode, the processing step produces a description of the work carried out by the lifting machine, the description taking at least one form from a graph representing the at least one carried out work, according to the category of carried out work, as a function of a time represented along a time axis, a pie chart type diagram representative of a relative importance of the at least one parameter associated with the at least one category of work, a summary table of values of the at least one parameter associated with the at least one work category, a three-dimensional representation of a start and end point of at least one carried out work falling within at least one work category.

According to one implementation mode, the method further comprises a step of comparing the at least one carried out work falling within the at least one category of carried out work with at least one planned work, in order to determine a difference between the at least one carried out work and at least one planned work.

According to one implementation mode, the step of processing the collected information is carried out locally on the lifting machine.

According to one implementation mode, the method further comprises a step of transmitting the collected information to a remote processing unit placed on a remote server and configured to implement the step of processing the collected information.

According to one implementation mode, the method further comprises a step of transmitting, to a display unit placed locally on the lifting machine, the description of the at least one carried out work during the processing step, to allow local display and monitoring of the carried out work.

According to one implementation mode, the processing step is carried out locally on the local processing unit of the lifting machine or on said remote processing unit located on the remote server.

According to one implementation mode, the display step is carried out locally on the display unit of the lifting machine or on a remote display unit and for example associated with the remote server.

According to one aspect, the present disclosure concerns a lifting system comprising a lifting machine and a remote server, the lifting machine comprising a control-command unit of the lifting machine, the lifting machine further comprising a collection unit configured to collect information from the control-command unit of the lifting machine for at least one period of time, the collection unit being configured to transmit the collected information to a remote processing unit, arranged on the remote server, the remote processing unit being configured to carry out a processing of the collected information to determine work carried out by the lifting machine during at least one period of time, the carried out work falling within at least one category of work, and to determine at least one parameter associated with the at least one carried out work and/or with the at least one category of carried out work, said processing comprising an implementation by the remote processing unit an artificial intelligence algorithm trained during a learning phase to carry out said processing during a predictive phase, the artificial intelligence algorithm using at least one piece of contextual information to determine the carried out work and/or or the category of carried out work, the contextual information being at least one of a lifting time, a maximum load, a maximum speed, a position of a load pick-up point and a position of a load drop-off point, a location of a delivery point, a location of a storage area.

According to another aspect, the present disclosure concerns a lifting machine, comprising a control-command unit of the lifting machine and a local processing unit arranged on the lifting machine, the lifting machine further comprising a collection unit configured to collect information for at least one period of time from the control-command unit of the lifting machine, the collection unit being configured to transmit the collected information to the local processing unit, arranged on the lifting machine, the local processing unit being configured to carry out a processing of the collected information to determine work carried out by the lifting machine during the at least one period of time, the carried out work falling within at least one category of work, and to determine at least one parameter associated with the at least one carried out work and/or with the at least one category of carried out work, said processing comprising an implementation by the unit processing an artificial intelligence algorithm trained during a learning phase to carry out said processing during a predictive phase, the artificial intelligence algorithm using at least one piece of contextual information to determine the carried out work and/or the category of carried out work, the contextual information being at least one of a lifting time, a maximum load, a maximum speed, a position of a load pick-up point and a position of a load drop-off point, a location of a delivery point, a location of a storage area.

According to one embodiment, the local processing unit and/or the remote processing unit is/are further configured to produce a description of the work carried out by the lifting machine.

### BRIEF DESCRIPTION OF THE DRAWINGS

For its proper understanding, an embodiment and/or implementation of the present disclosure is described with reference to the attached drawings representing, by way of non-limiting example, an embodiment or implementation respectively of a device and/or a method according to the present disclosure. The same references in the drawings designate similar elements or elements with similar functions.

FIG. 1a is a first schematic and simplified view of a lifting machine on a construction site, configured for the implementation of the method according to an example of the present disclosure;

FIG. 1b is a second schematic and detailed view of the lifting machine of FIG. 1a;

FIG. 2 is a simplified diagram of the sequence of steps of the method according to the present examples;

FIG. 3 is an example of a chronogram produced by the method according to the invention, in which the different categories of work carried out by the lifting machine are represented as a function of a time, along a time axis T, each category of carried out work being represented by a particular color;

FIG. 4 is a representation example of a distribution of the different categories of carried out work by the lifting machine, the distribution being determined on the basis of a particular metric or parameter, such as a duration of the carried out work, a number of carried out lifts, or a duration of movements of the lifting machine;

FIG. 5 is an example of a three-dimensional representation of the positions in space of the start and end points of the carried out work;

FIG. 6 represents a phase of collecting different load signals corresponding to different lifting machines present on different construction sites;

FIG. 7 represents three load signal levels respectively representative of three categories of carried out work;

FIG. 8 represents a phase of transmitting, to the local processing units of the lifting machine, of the different determined load signal profiles; and

FIG. 9 schematically represents, for a single lifting machine present on a given site, the collection phase represented in FIG. 6 and the transmission phase represented in FIG. 8.

### DESCRIPTION

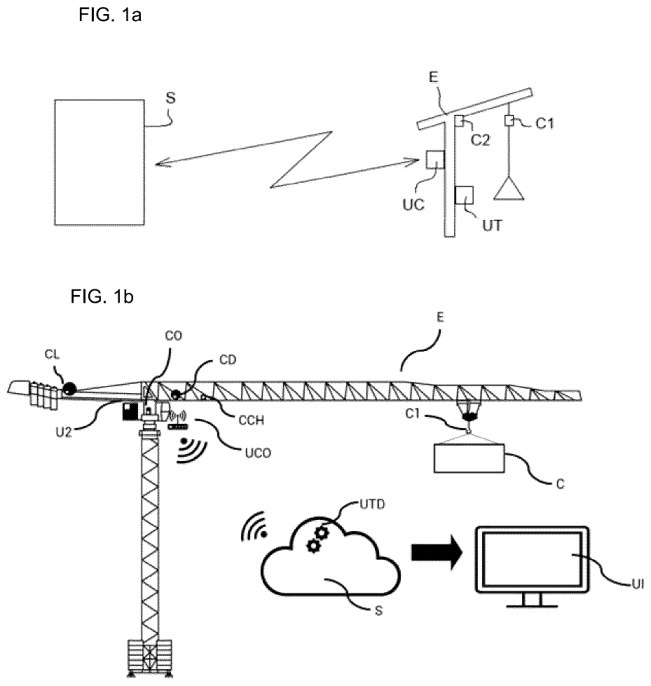

The present disclosure concerns a method 100 for automatically determining the work carried out by a lifting machine E, for example a crane, shown schematically by way of example in FIGS. 1a and 1b. The lifting machine E comprises a control-command unit C2 configured to communicate with various sensors installed on the lifting machine E; for example, the different sensors comprise a load measurement sensor CCH, that is to say a sensor for measuring a mass of a load C lifted by a hook C1 of the lifting machine E, and sensors for positioning the movable parts of the lifting machine E such as for example a lifting encoder CL, an orientation encoder CO or even a distribution encoder CD.

The lifting encoder CL gives an image of the height of the lifting hook of the lifting machine.

The distribution encoder CD gives an image of the position of the carriage, and therefore of the lifting hook of the lifting machine, relative to its axis of rotation between its fixed (mature) part and its rotating part.

The orientation encoder CO gives an image of the angle of the rotating part of the lifting machine relative to a reference angle of its fixed (mature) part.

The control-command unit C2 is further configured to command the implementation of the lifting machine E, depending in particular on the measurements rendered by said sensors, for the production, during different periods of time, of different categories of works T1, T2, T3, T4, T5, T6, such as for example a concrete casting, a transfer or positioning of a type of load, a no-load movement, or other, for example an unloading of a truck of materials, optionally, it will also be considered, among the categories of carried out work, periods of inactivity or periods of indefinite activity.

More particularly, the type of load comprises a concrete bucket, a rubble bucket, one or more construction materials, for example a group of props, one or more formwork elements (also called formwork), one or more concrete reinforcement elements, a prefabricated element, for example a staircase, a balcony, a double wall.

The lifting machine E further comprises collection unit UC configured to capture different signals used by the control-command unit C2 to implement and command the lifting machine E as the various categories of work.

The information thus collected by the collection unit UC comprises in particular a load signal, representative of a mass of the load C lifted by the lifting machine E over time, a position signal in the space of a hook C1 of the lifting machine E, a speed signal representative of a variation of the frequency variators and a signal representative of an electrical state of the lifting machine E. This list is not exhaustive.

The collected information is provided as input to a local processing unit UT and/or a remote processing unit UTD. The remote processing unit UTD can be placed on a remote server S, with which the collection unit UC is configured to communicate via a communication unit UCO of the lifting machine E capable of transmitting and receiving information exchanged for example over an extended network such as the Internet. The local processing unit UT can be installed locally near or directly on the lifting machine E, the collection unit UC being configured to communicate with the local processing unit UT via a wired or wireless link.

The local processing unit UT and/or the remote processing unit UTD is/are configured to implement an artificial intelligence algorithm trained to determine from the information collected by the collection unit UC, a category of work carried out by the lifting machine E, for example a concrete casting, a displacement of a type of load, a transfer of a type of load or an unloading of a truck of materials, and to determine different parameters associated with the category of carried out work, for example a duration of said carried out work, a mass of a load lifted during said carried out work, a movement of a load lifted during said category of carried out work; the artificial intelligence algorithm is trained to also determine, from the information collected over different periods of time, a traveled distance, and an associated speed of displacement, between the load pick-up point and the drop-off point, or an average duration of the work carried out falling within said category of work, or a maximum duration of the work carried out falling within said category of work, or a minimum duration of the work carried out falling within said category of work, or a minimum mass lifted during the work carried out falling within said category of work, or a maximum mass lifted during the work carried out falling within said category of work.

The artificial intelligence algorithm is for example implemented by an unsupervised temporal analysis grouping algorithm comprised in the local processing unit UT and/or the remote processing unit UTD.

The training of the artificial intelligence algorithm can be carried out from a set of training data, collected via the collection unit UC; a phase of cleaning, normalization and grouping of the information collected by profile and trend via dynamic time deformation, is planned before learning the artificial intelligence algorithm, in order to improve the learning results.

The implemented artificial intelligence algorithm is based for example on a profile, i.e. on a shape or a «head», of the temporal load signal; this has the advantage of being simple and relatively inexpensive in terms of calculation time.

According to an implementation example, in order to reduce the proportion of classification error of carried out work, i.e. the proportion of lifting cycles which are not classified in the expected category of carried out work, for example a concrete casting detected as a prefabricated positioning, the artificial intelligence algorithm is enriched with contextual data relating to these intrinsic characteristics. According to an example of taking into consideration contextual data by the artificial intelligence algorithm, when it is known that the mixer truck delivers concrete to a delivery point known by its location, the artificial intelligence algorithm uses this contextual information to deduce that a lifting cycle which begins or ends near this known location corresponds to a casting cycle. According to another example of taking into consideration contextual data by the artificial intelligence algorithm, when it is known that delivery trucks park at another known delivery point, that the equipment or raw materials delivered are stored in a storage area of known location, the artificial intelligence algorithm uses this contextual information, known location of the other delivery point and known location of the storage area, to deduce that a lifting cycle whose pick-up point corresponds to the known location of the other delivery point, and whose drop-off point corresponds to the known location of the storage area, corresponds to «truck unloading» type work.

Thus, the artificial intelligence algorithm can take into account different contextual data associated with different characteristics of a lifting cycle, such as lifting time, a maximum load, a maximum speed, a position of a load pick-up point and a position of a load drop-off point.

Thus, the method 100 allows the automated determination of the types of activity, i.e. the categories of work T1, T2, T3, T4, T5, T6, carried out by the lifting machine E, with their duration, the associated movements, the lifted load, etc.

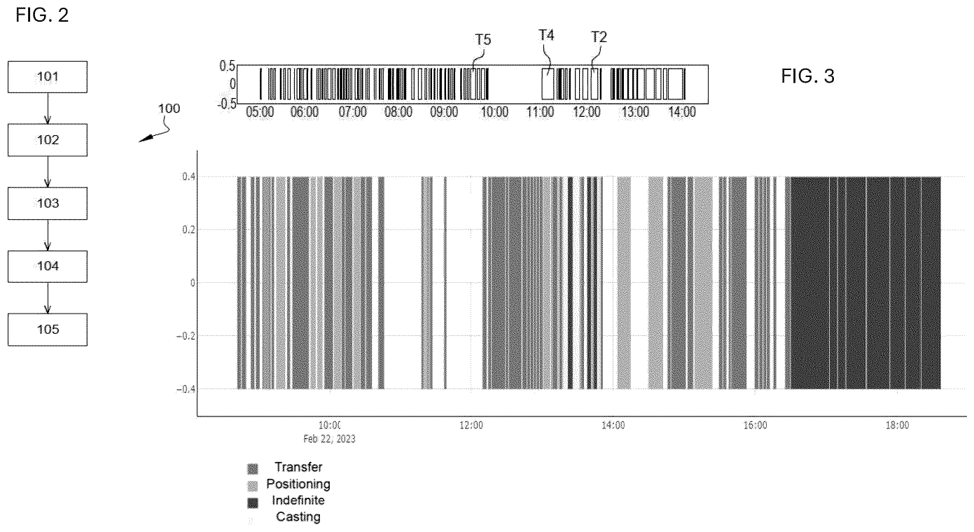

With reference to FIG. 2, the method 100 comprises the following steps:
a step 101 of collecting, for at least one period of time, by a collection unit UC, information coming from a control-command unit C2 of the lifting machine E;
a step of processing 103 the information collected by the collection unit UC to determine work carried out by the lifting machine E during at least one period of time, the carried out work falling within at least one category of carried out work T1, T2, T3, T4, T5, T6, and to determine at least one parameter associated with the at least one carried out work and/or with the at least one category of carried out work T1, T2, T3, T4, T5, T6.

Optionally, the method 100 further comprises a step 102 of transmitting the collected information to the remote processing unit UTD located on the remote server S and configured to implement the processing step 103 of the collected information. According to another option, the processing step 103 of the collected information is carried out locally on the local processing unit UT of the lifting machine E.

The table below illustrates by way of example the information that the method 100 according to the present disclosure makes it possible to automatically determine from the control-command information collected via the collection unit UC.

TABLE 1

| Category of | Number | Total | Average | Maximum | Average | Maximum |
|---|---|---|---|---|---|---|
| carried out work | of lifts | duration | duration | duration | load (kg) | load (kg) |
| Transfer: T1 | 339 | 10:46:40 | 00:02:45 | 00:10:15 | 1245 | 5642.5 |
| Positioning: T2 | 134 | 06:17:06 | 00:07:50 | 00:18:52 | 1859 | 4221.25 |
| Casting: T5 | 30 | 03:55:16 | 00:04:13 | 00:10:49 | 888 | 3437.5 |
| Undefined: T4 | 14 | 00:59:14 | | | | |
| Inactive: T3 | | 3:29:56 | | | | |
| No-load movements: T6 | | 5:24:14 | | | | |
| Other | | 9:17:36 | | | | |

The number of categories of work, and the «fineness» of these categories, is directly linked to the number of parameters, determined during the processing step 103 of the collected information, and taken into account for the determination and categorization of the carried out work when sufficient contextual parameters are found to differentiate one class from another class.

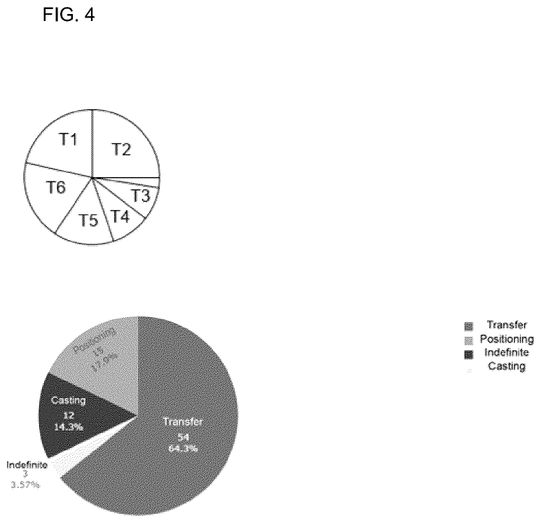

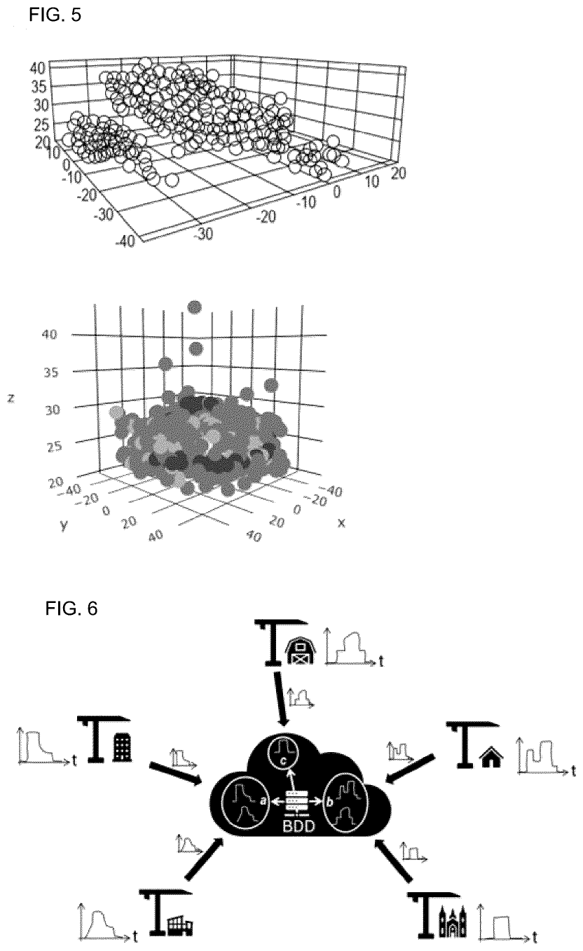

According to an implementation example, the processing step 103 is configured to produce a description of the carried out work by the lifting machine E, the description taking the form of a graph or chronogram representing said carried out work presented chronologically, for example by color code, along a time axis T, as illustrated in FIG. 3; the description can also take the form of a pie chart representing the relative importance of the value of a particular parameter, for example a work duration, associated with said carried out work T1, T2, T3, T4, T5, T6, as illustrated in FIG. 4; the description can also take the form of a summary table of the values of the different parameters associated with the different carried out work, such as for example table 1 above; the description can also take the form of a representation of the start and end positions of the carried out work, measured in three dimensions in a reference frame defined by three axes X, Y, Z, as is illustrated by way of example in FIG. 5.

Optionally, the method 100 further comprises a step 104 of comparing the carried out work with a planned work program, in order to determine a difference between the carried out work and the planned work.

Optionally also, the method 100 further comprises a step of transmitting 105, to a display unit UI arranged locally on the lifting machine E or remotely, of the description of the at least one carried out work produced during the processing step 103, to allow local display and monitoring of the carried out work.

According to one possibility, the display unit UI further comprises a user interface allowing a user to interact with the display unit UI.

Thus, the processing step can be carried out locally on the local processing unit UT of the lifting machine E, or on a remote processing unit UTD located on the remote server S.

Likewise, the display step for purposes of monitoring the carried out work can be carried out locally on the display unit of the lifting machine E, or on a display unit placed remotely and for example associated to the remote server S.

Thus, according to one aspect, the present disclosure concerns a lifting system comprising a lifting machine E and a remote server S, the lifting machine E comprising a control-command unit C2 of the lifting machine E, the lifting machine E further comprising a collection unit UC configured to carry out a collection step 101 for at least one period of time of information coming from the control-command unit C2 of the lifting machine E, the collection unit UC being configured to transmit the collected information to a remote processing unit UTD located on the remote server S, the remote processing unit UTD being configured to carry out a processing step 103 of the information collected by the collection unit UC to determine carried out work by the lifting machine E during the at least one period of time, the carried out work falling within at least one category of carried out work T1, T2, T3, T4, T5, T6, and to determine at least one parameter associated with the at least one carried out work and/or with the at least one category of carried out work T1, T2, T3, T4, T5, T6.

According to another aspect, the present disclosure also concerns a lifting machine E, comprising a control-command unit C2 of the lifting machine E and a local processing unit UT arranged on the lifting machine E, the lifting machine E further comprising a collection unit UC configured to carry out a collection step 101 for at least one period of time of information coming from the control-command unit C2 of the lifting machine E, the collection unit UC being configured to transmit the collected information to the local processing unit UT arranged on the lifting machine E and/or to a remote processing unit UTD, the local processing unit UT and/or the remote processing unit UTD being configured to carry out a processing step 103 of the information collected by the collection unit UC to determine work carried out by the lifting machine E during the at least one period of time, the carried out work falling within at least one category of carried out work T1, T2, T3, T4, T5, T6, and to determine at least one parameter associated with the at least one carried out work and/or with the at least one category of carried out work T1, T2, T3, T4, T5, T6.

According to an embodiment, the local processing unit UT and/or the remote processing unit UTD is/are configured to implement an artificial intelligence algorithm trained during a learning phase to carry out the processing step 103 during a predictive phase, using at least one contextual information to determine the carried out work and/or the category of carried out work and to produce a description of the carried out work by the lifting machine E.

According to one possibility, the learning phase of the artificial intelligence algorithm comprises a data collection phase from the control-command units of lifting machines operating on different construction sites, as shown in FIG. 6.

According to one possibility, the collection phase makes it possible to collect data representative of the different load signals corresponding to each lifting machine present on each of the considered sites, which makes it possible to constitute and continuously enrich a remote database BDD with a significant amount of load signals.

Likewise, the collection phase can, depending on one possibility, make it possible to collect contextual information, which can also enrich a remote database.

Such enrichment makes it possible to extract and determine different load signal profiles, each of said profiles being representative of a category of carried out work.

Thus, the learning phase of the artificial intelligence algorithm makes it possible to determine at least one profile of model load signal, which is representative of a category of carried out work.

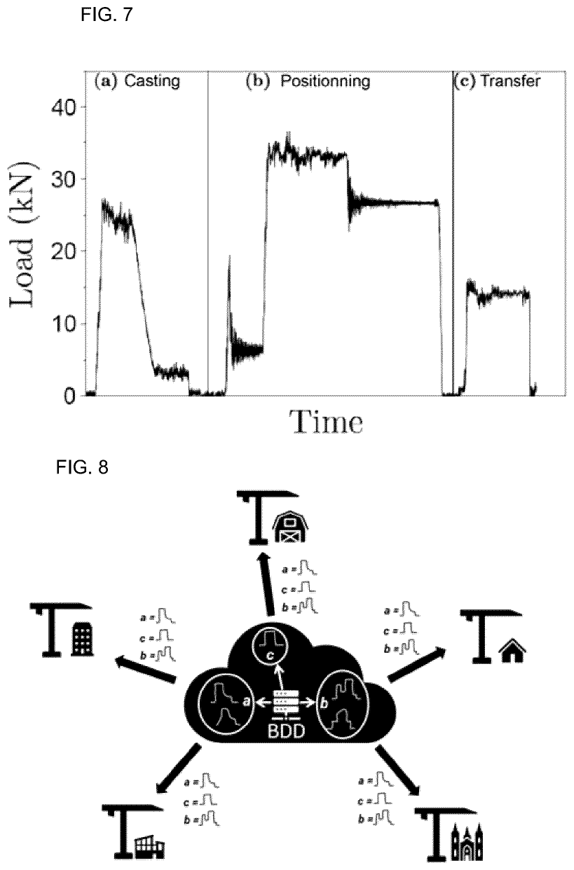

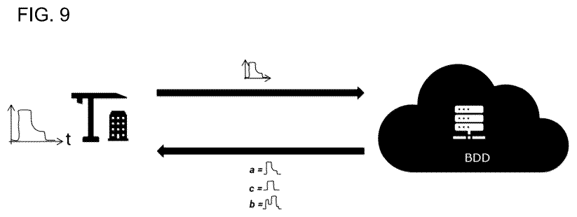

For example and as shown in FIG. 7 in which the abscissa axis is representative of a duration and the ordinate axis is expressed in kilo Newton (kN), a first load signal profile a is representative of a concrete casting, a second load signal profile b is representative of a positioning of a load type, and a third load signal profile c is representative of a transfer of a load type.

Once determined, the different model load signal profiles, or typical profiles a, b, c can be communicated to the local/remote processing units of each lifting machine, as shown in FIG. 8. This allows each local/remote processing unit to have the different model profiles of the load signal, in order to be able to recognize, via a profile comparison step via a distance calculation based on a dynamic time deformation, then to classify the load signal of the corresponding lifting equipment according to one of the categories of carried out work.

1-13. (canceled)

14. An automated method for establishing an inventory of the categories of work carried out during different periods of time by a lifting machine, the method comprising the following steps:
a step of collecting for at least one period of time, by a collection unit, information coming from a control-command unit of the lifting machine; and
a step of processing, by a local processing unit and/or a remote processing unit, information collected by the collection unit to determine work carried out by the lifting machine during the at least one period of time, the carried out work falling within at least one category of carried out work, and to determine at least one parameter associated with the at least one carried out work and/or with the at least one category of carried out work,
wherein the processing step comprises an implementation by the local processing unit and/or the remote processing unit of an artificial intelligence algorithm trained during a learning phase to carry out the processing step during a predictive phase, and
wherein the artificial intelligence algorithm uses at least one contextual information to determine the carried out work and/or the category of carried out work, the contextual information being at least one among a lifting time, a maximum load, a maximum speed, a position of a load pick-up point and a position of a load drop-off point, a location of a delivery point, a location of a storage area.

15. The method according to claim 14, wherein the collected information comprises at least one of a load signal, representative of a mass of a load lifted by the lifting machine, a position signal in the space of a hook of the lifting machine, a speed signal representative of a variation of the frequency variators and a signal representative of an electrical state of the lifting machine.

16. The method according to claim 15, wherein a load signal coming from the collection step is compared to a set of model signals determined by a learning phase of the artificial intelligence algorithm.

17. The method according to claim 14, wherein the at least one category of carried out work during the at least one period of time comprises at least one of a concrete casting, a transfer of a type of load, a positioning of a type of load, a no-load movement, an unloading of a truck of materials.

18. The method according to claim 14, wherein the type of load comprises at least one of a concrete bucket, a rubble bucket, one or more construction materials, one or more formwork elements, one or more concrete reinforcement elements, a prefabricated element.

19. The method according to claim 14, wherein the at least one parameter associated with the at least one category of carried out work comprises at least one among a duration of carried out work falling within said at least one category of work, a mass of a load lifted during carried out work falling within the at least one category of work, a movement of a load lifted during carried out work falling within at least one category of work, an average duration of the carried out work, during different periods of time, falling within said category of work, a maximum duration of the carried out work, during different periods of time, falling within said category of work, a minimum duration of the carried out work, during different periods of time, falling within said category of work, a minimum mass lifted during the carried out work, during different periods of time, falling within said category of work, a maximum mass lifted during carried out work, during different periods of time, falling within said category of work.

20. The method according to claim 14, wherein the processing step produces a description of the work carried out by the lifting machine, the description taking at least one form from a graph representing the at least one carried out work, according to the category of the carried out work, as a function of a time represented along a time axis, a pie chart type diagram representative of a relative importance of the at least one parameter associated with the at least one category of work, a summary table of values of the at least one parameter associated with the at least one category of work, a three-dimensional representation of a start and end point of at least one carried out work falling within at least one category of work.

21. The method according to claim 14, further comprising a step of comparing the at least one carried out work falling within the at least one category of carried out work with at least one planned work, in order to determine a difference between the at least one carried out work and the at least one planned work.

22. The method according to claim 14, wherein the processing step of the collected information is carried out locally on the lifting machine.

23. The method according to claim 14, further comprising a step of transmitting the collected information to a remote processing unit located on a remote server configured to implement the processing step of the collected information.

24. The method according to claim 22, further comprising a step of transmitting the collected information to a remote processing unit located on a remote server configured to implement the processing step of the collected information; and
a transmission step to a display unit arranged locally on the lifting machine or remotely, of the description of the at least one carried out work produced during the processing step, to allow local display and monitoring of the carried out work.

25. A lifting system comprising a lifting machine and a remote server, the lifting machine comprising a control-command unit of the lifting machine, the lifting machine further comprising a collection unit configured to carry out a collection step for at least one period of time of information coming from the control-command unit of the lifting machine, the collection unit being configured to transmit the collected information to a local processing unit and/or a remote processing unit located on the remote server, the local processing unit and/or the remote processing unit being configured to carry out a processing step of the information collected to determine work carried out by the machine lifting during at least one period of time, the carried out work falling within at least one category of work, and to determine at least one parameter associated with the at least one carried out work and/or the at least one category of carried out work, in which the processing step comprises an implementation by the local processing unit and/or the remote processing unit of an artificial intelligence algorithm trained during a learning phase to carry out, during a predictive phase, the processing step, and in which the artificial intelligence algorithm uses at least one contextual information to determine the carried out work and/or the category of carried out work, the contextual information being at least one among a time lifting capacity, a maximum load, a maximum speed, a position of a load pick-up point and a position of a load drop-off point, a location of a delivery point, a location of a storage area.

26. A lifting machine, comprising a control-command unit of the lifting machine and a local processing unit arranged on the lifting machine, the lifting machine further comprising a collection unit configured to carry out a step of collecting for at least one period of time information coming from the control-command unit of the lifting machine, the collection unit being configured to transmit the collected information to the local processing unit, arranged on the lifting machine, the local processing unit being configured to carry out a processing step of the information collected to determine work carried out by the lifting machine during the at least one period of time, the carried out work falling within at least one category of work, and to determine at least one parameter associated with the at least one carried out work and/or with the at least one category of carried out work, in which the processing step comprises an implementation by the local processing unit of an artificial intelligence algorithm trained during a learning phase to carry out the processing step during a predictive phase, and in which the artificial intelligence algorithm uses at least one piece of contextual information to determine the carried out work and/or the category of carried out work, the contextual information being at least one among a lifting time, a maximum load, a maximum speed, a position of a load pick-up point and a position of a load drop-off point, a location of a delivery point, a location of a storage area.
